(19) United States
(12) Patent Application Publication
(10) Pub. No.: US 2026/0290490 A1
(43) Pub. Date: Sep. 24, 2026

(54) APPARATUSES AND METHODS FOR THE RESET OF PER ROW ACTIVATION COUNT FOR ROWS DISABLED DURING SOFT POST-PACKAGE REPAIR

(71) Applicant: Micron Technology, Inc., Boise, ID (US)

(72) Inventors: John E. Riley, McKinney, TX (US); Yang Lu, Boise, ID (US); Randall J. Rooney, Boise, ID (US)

(73) Assignee: Micron Technology, Inc., Boise, ID (US)

(21) Appl. No.: 19/568,662

(22) Filed: Mar. 16, 2026

Related U.S. Application Data
(60) Provisional application No. 63/775,796, filed on Mar. 21, 2025.

(51) Int. Cl. G11C 29/00; G11C 11/406; G11C 11/4076

(52) U.S. Cl. CPC G11C 29/76; G11C 11/40622; G11C 11/4076

(57) ABSTRACT

Embodiments of the disclosure are drawn to apparatuses, systems, and methods for managing sPPR undo operations based on activation count values of original rows after a repair. After packaging, it may be necessary to perform post-package repair operations on rows of the memory. During an sPPR operation, an address of an original row of memory may be associated with an open repair address instead, such as when the original row is determined to be damaged or defective. The sPPR repair may be reversed by performing an sPPR undo operation. While the repair row is associated with the original row, the activation count of the original row may become corrupted, and it may be necessary to reset the activation count associated with the original row during a repair undo operation to prevent unnecessary refresh operations occurring on the original row and adjacent rows.

### CROSS-REFERENCE TO RELATED APPLICATIONS

This application claims the filing benefit of U.S. Provisional Application No. 63/775,796, filed Mar. 21, 2025. This application is incorporated by reference herein in its entirety and for all purposes.

### BACKGROUND

This disclosure relates generally to semiconductor devices, and more specifically to semiconductor memory devices. In particular, the disclosure relates to memory, such as dynamic random-access memory (DRAM), and memory controllers. Information may be stored on individual memory cells of the memory as a physical signal, such as a charge on a capacitive element. At various points in manufacturing and use of a memory device, one or more memory cells may fail. For example, memory cells may become unable to store information, be inaccessible by the memory device, etc. When one or more memory cells fail, they may need to be repaired.

The memory device may perform repair operations on a row-by-row basis. A row containing a failed memory cell may be identified. The memory device may contain additional rows of memory which may be used in repair operations. During a repair operation, an address associated with the defective row may be redirected, such that the address points to a repair row instead.

As memory components have decreased in size, the density of memory cells has greatly increased. Repeated activation of a particular memory cell or group of memory cells may cause an increased rate of data degradation in nearby memory cells. Memory devices use various schemes to identify addresses that are repeatedly activated so that the nearby memory cells may be refreshed. One way to identify addresses that are repeatedly activated is to keep a count of the number of activations for a particular row. The count may need to be reset to a starting value if a row has been deactivated for a long period of time because the count may be in an unknown or inaccurate state. Inaccurate count values may cause false identification of attacks.

### BRIEF DESCRIPTION OF THE DRAWINGS

FIG. 1 illustrates a block diagram of an example system according to an embodiment of the disclosure.

FIG. 2 illustrates a block diagram of an example memory rank according to an embodiment of the disclosure.

FIG. 3 is a block diagram of a memory device according to at least some embodiment of the disclosure.

FIG. 4 is a flow diagram of a repair operation according to some embodiments of the present disclosure.

FIG. 5 is a flow diagram of a repair undo operation according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory system may include a plurality of memory ranks that each include one or more memory devices. The one or more memory devices may include one or more memory dies. Semiconductor memory devices may store information in a plurality of memory cells. The information may be stored as a binary code and each memory cell may store a single bit of information as either a logical high (e.g., a “1”) or a logical low (e.g., a “0”). The memory cells may be organized at the intersection of word lines, or rows, and bit lines, or columns. The memory may further be organized into one or more memory banks, each of which may include a plurality of rows and columns. During operations, the memory device may receive a command and an address which specifies one or more rows and one or more columns then execute the command on the memory cells at the intersection of the specified rows and columns and/or along an entire row/column.

A memory bank may include original rows that are identified by respective row addresses. The original rows may also be known as prime rows. The memory banks may also include repair rows of memory to which the address of an original row including defective memory cells may be remapped. The repair rows may also be known as redundant rows. In this manner, a defective original row may be “repaired” by accessing a repair row designated for the row address instead of the defective original row. Certain memory cells may be defective or there may be reasons to need redundant storage associated with a certain memory cell. In some cases, the original rows may be incapable of storing information and/or may become otherwise inaccessible to the memory die. The memory cells may become defective, or may be identified as defective, after the memory system is packaged in which case the memory die may carry out one or more types of post-package repair (PPR) operation to resolve the defective rows.

As previously described, memory banks may include a number of additional rows of memory, which may generally be referred to as repair rows or redundant rows. During a repair operation, a row address associated with an original row may be redirected so that it is associated with one of the repair rows instead. In some modes of operation, the repair operation may be a “hard,” or permanent, repair operation, where updated row address information is stored in the memory in a non-volatile form. Repair operations may also be “soft,” where row address information is associated with a repair row in a volatile form.

During a soft PPR (sPPR) operation, volatile elements may be used to track repairs. During an sPPR operation performed on a given row, the address of the open repair row and the address of the row to be repaired, or the original row, may be stored in volatile elements, such as latch circuits, so that information which would have been directed to the row to be repaired, or the original row, is directed to the repair row instead.

Various patterns of activating a row, which may be a repair row or an original row, may cause an increased rate of information decay in memory cells along nearby rows. A row experiencing such patterns of activation may be called an aggressor row and the nearby rows may become victim rows. For example, repeated activation of the aggressor row may increase a rate of decay in adjacent rows and/or in rows which are farther away. This increased rate of decay, above the rate expected by the refresh timing, may risk the loss of information in the victim rows. Accordingly, some memories may track a number of activations of each row, including repair rows, to determine if they are aggressors so that victim rows can be identified and refreshed as part of a targeted refresh operation.

Counting activations of each row may be referred to as a per row activation counter (PRAC) scheme. In some embodiments, to implement such a scheme, each word line of a memory array has an associated activation count value stored in counter memory cells. The activation count value is used to determine how many times that word line has been activated. When the word line is activated the activation count value may be changed, for instance incremented, by a counter circuit and compared to a mitigation threshold by a comparator. If the activation count value crosses the mitigation threshold, then the address may be added to an aggressor queue and during targeted refresh operations, the addresses in the queue are used to generate refresh addresses.

There may be times when the counter memory cells have an unknown state. For example, after power up, the counter memory cells may be populated with random-like bits. If the memory is immediately used, the random state of the bits may create various issues, such as an illusion of an aggressor. An illusion of an aggressor may occur because some activation count values start at a much higher value due to the random bits assigned at power up. To prevent an illusion of an aggressor, the memory device may reset the counter memory cells to a known value. For example, the memory device may perform an activation count update (ACU) operation to reset the counter memory cells when a row is refreshed. The memory device may reset the counter memory cells to an initial value. The initial value may be such that it is known by the memory device or falls within a known range. There may be other situations which require resetting of the activation counters, for example, if refresh requirements are violated and the counters are placed in an unknown state. To prevent the random state of the activation count values from causing undesired memory operations, the memory may reset the activation count values.

Another example which may require the memory device to reset the activation counter may be during a repair undo operation. When an original row is repaired, it is deactivated and thus, the counter memory cells associated with the original row will not be updated while the original row operations are diverted to a repair row. The counter memory cells may have an unknown state when a repair undo operation is initiated to redirect row operations back to the original row and the memory device may reset the counter memory cells to a known value.

The present disclosure is drawn to apparatuses, systems, and methods for managing repair and repair undo operations. In some embodiments of the disclosure, the repair and repair undo operations include sPPR and sPPR undo operations. A memory of a memory system may receive a repair command. Responsive to the repair command, the memory may perform a repair operation. Responsive to the repair operation, the memory may activate a repair row of memory devices included in the memory. A repair row may be a repair word line WLR, or redundant word line, of a memory array in the memory devices. Responsive to the repair operation performed based on the repair command, a timer may be started. The timer may keep track of the amount of time that has passed since the repair operation began.

The timer may count time until the time value reaches a threshold amount of time. The threshold amount of time may be a predetermined amount of time and may represent the amount of time that can pass before the value written to the counter memory cells associated with the original row is no longer trustworthy, or in other words, the value may have been corrupted or otherwise entered an unknown state. In some embodiments, when the timer reaches the threshold amount of time, the memory device may block repair undo operations from being performed. In yet other embodiments, when the timer reaches the threshold amount of time, the memory device may reset the counter memory cells associated with the original row.

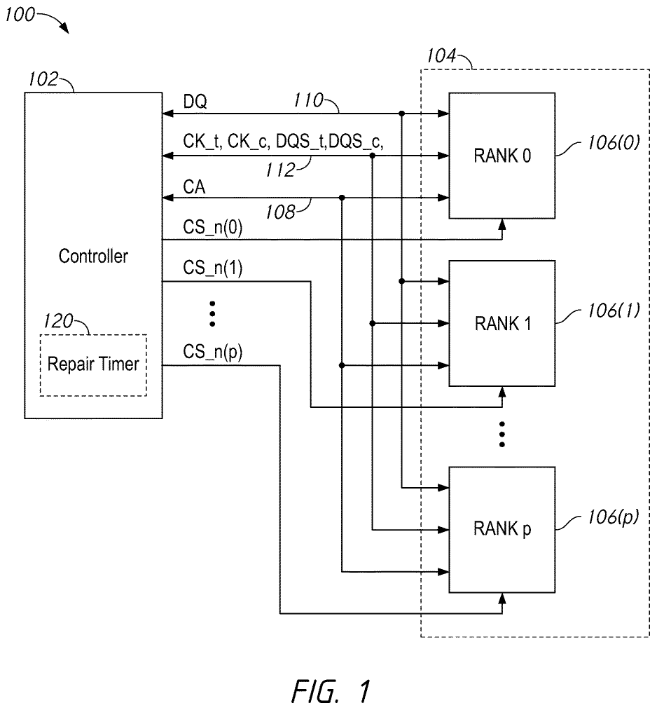

FIG. 1 illustrates a block diagram of an example system according to an embodiment of the disclosure. The system 100 includes a controller 102 and a memory system 104. In the illustrated embodiment, the memory system 104 includes memory ranks 106(0)-106(p) (e.g., “Rank 0” through “Rank p”), where p is a number greater than one (1).

Each memory rank can include one or more memory devices (e.g., DRAM devices) or memory dies. For example, the memory ranks 106(0)-106(p) may include a DRAM, a double data rate (DDR) memory, a low power double data rate (LPDDR) memory, a graphics double data rate (GDDR) memory, or other type of memory.

The memory ranks 106(0)-106(p) are each coupled to the command/address, data, and clock buses. The controller 102 and the memory system 104 are in communication over several buses. Commands and addresses (CA) are received by the memory system 104 on a command/address bus 108, and data (DQ) is provided between the controller 102 and the memory system 104 over a data bus 110. Various clocks may be provided between the controller 102 and the memory system 104 over a clock bus 112. The clock bus 112 may include signal lines for providing system clocks CK_t and CK_c received by the memory system 104 and data clocks (strobes) DQS_t and DQS_c received by the memory system 104 and/or provided to the controller 102. Each of the buses may include one or more signal lines on which signals are provided.

The CK_t and CK_c clocks provided by the controller 102 to the memory system 104 are used for timing the provision and receipt of the commands and addresses. The DQS_t and DQS_c clocks are used for timing provision of data. The CK_t and CK_c clocks are complementary, and the DQS_t and DQS_c clocks are complementary. Clocks are complementary when a rising edge of a first clock occurs at a same time as a falling edge of a second clock, and when a rising edge of the second clock occurs at a same time as a falling edge of the first clock.

The controller 102 provides commands to the memory system 104 to perform memory operations. Examples of memory commands include timing commands for controlling the timing of various operations, repair mode entry and exit commands, access commands for accessing the memory, such as read commands for performing read operations and write commands for performing write operations, activate commands, refresh command, precharge command, deselect command, no operation commands, as well as other commands. The command signals provided by the controller 102 to the memory system 104 further include external control signals (e.g., chip select signals CS_n(0), CS_n(1), CS_n(p)).

The memory ranks 106(0)-106(p) are provided the commands, addresses, data, and clocks, and the external control signals provided on respective select signal lines are used to select which of the memory ranks 106(0)-106(p) will respond to the command and perform the corresponding operation. In some embodiments, a respective control signal is provided to each memory rank 106(0)-106(p) of the memory system 104. In some embodiments, the memory dies included in a rank are provided a same control signal. The controller 102 provides an active control signal to select the corresponding memory rank 106(0)-106(p). While the respective control signal is active, the corresponding memory rank 106(0)-106(p) is selected to receive the commands and addresses provided on the command/address bus 108. In some embodiments, the external control signal is used in combination with the CA signals to indicate different memory commands and memory operations.

In operation, when an activate and a read command, and associated address are provided by the controller 102 to the memory system 104, the memory rank 106(0)-106(p) selected by the external control signals receives the activate and read commands and associated address and performs a read operation to provide the controller 102 with read data from a memory location corresponding to the associated address. The read data is provided by the selected memory rank 106(0)-106(p) to the controller 102 according to a timing relative to receipt of the read command. For example, the timing may be based on a read latency (RL) value that indicates the number of clock cycles of the CK_t and CK_c clocks (a clock cycle of the CK_t and CK_c clocks is referenced as tCK) after the read command when the read data is provided by the selected memory rank 106(0)-106(p) to the controller 102.

In preparation of the selected memory rank 106(0)-106(p) providing the read data to the controller 102, the memory device provides active data clocks DQS_t and DQS_c. A clock is active when the clock transitions between low and high clock levels periodically. Conversely, a clock is inactive when the clock maintains a constant clock level and does not transition periodically. The DQS_t and DQS_c clocks are provided by the memory rank 106(0)-106(p) performing the read operation to the controller 102 for timing the provision of read data to the controller 102. The controller 102 may use the DQS_t and DQS_c clocks for receiving the read data.

In operation, when an activate command and a write command, and associated address are provided by the controller 102 to the memory system 104, the memory rank 106(0)-106(p) selected by the external control signals receives the activate and write commands and associated address and performs a write operation to write data from the controller 102 to a memory location corresponding to the associated address. The write data is provided to the selected memory rank 106(0)-106(p) by the controller 102 according to a timing relative to receipt of the write command. For example, the timing may be based on a write latency (WL) value that indicates the number of clock cycles of the CK_t and CK_c clocks after the write command when the write data is provided to the selected memory rank 106(0)-106(p) by the controller 102. The WL value is programmed by the controller 102 in the memory ranks 106(0)-106(p). For example, the WL value may be programmed in respective mode registers of the memory ranks 106(0)-106(p).

In preparation of the selected memory rank 106(0)-106(p) receiving the write data from the controller 102, the controller 102 provides active data clocks DQS_t and DQS_c to the memory system 104. The DQS_t and DQS_c clocks may be used by the selected memory rank 106(0)-106(p) to generate internal clocks for timing the operation of circuits to receive the write data. The data is provided by the controller 102 and the selected memory rank 106(0)-106(p) receives the write data according to the DQS_t and DQS_c clocks, which is written to a memory location corresponding to the memory address.

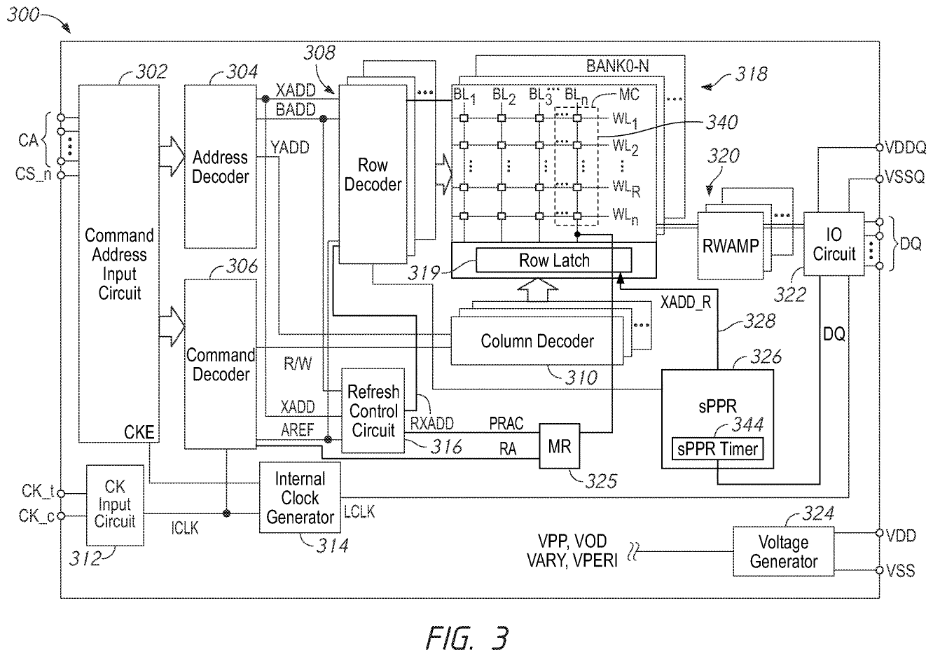

Mode register write commands and mode register read commands can be used to access the mode registers (e.g., mode register 325 in FIG. 3). In operation, when a mode register read (MRR) command and associated address are provided by the controller 102 to the memory system 104, the memory device selected by the select signals receives the mode register read command and associated address and performs a mode register read operation to provide the controller 102 with information from the mode register corresponding to the associated address. The information from the selected mode register is provided to the controller 102. When a mode register write (MRW) command and associated address are provided by the controller 102 to the memory system 104, the memory device selected by the select signals receives the mode register write command and associated address and performs a mode register write operation to write information provided by the controller 102 to a mode register corresponding to the associated address. The information is provided to the selected mode register by the controller 102. A mode register write command may provide information for setting various operating modes and/or to select features for operation of the memory dies and/or memory ranks 106(0)-106(p).

In some embodiments of the disclosure, mode register settings may include enabling a repair mode and/or a repair undo mode. The controller 102 may, in some embodiments, include a repair timer 120. For example, the repair timer 120 may start counting time when a repair command is issued for a row address. In some embodiments, when the time on the timer 120 reaches a threshold amount of time, a repair undo disable flag may be set to stop the memory controller 102 from transmitting repair undo commands for the row address of a particular memory bank. In some embodiments, the repair undo disable flag may be set to stop the memory controller 102 from transmitting repair undo commands for the row address on all memory banks. The repair undo disable flag may be reset responsive to a power cycle. In yet other embodiments, based on the time on the timer 120, an activation count associated with an original row may be reset or incremented when a repair undo command is issued. For example, if the time on the timer 120 is less than the threshold amount of time, the activation count may be incremented responsive to the repair undo command because the activation count may still be valid. If the time on the timer 120 reaches or passes the threshold amount of time, the activation count may be considered untrustworthy and reset to a known value responsive to the repair undo command.

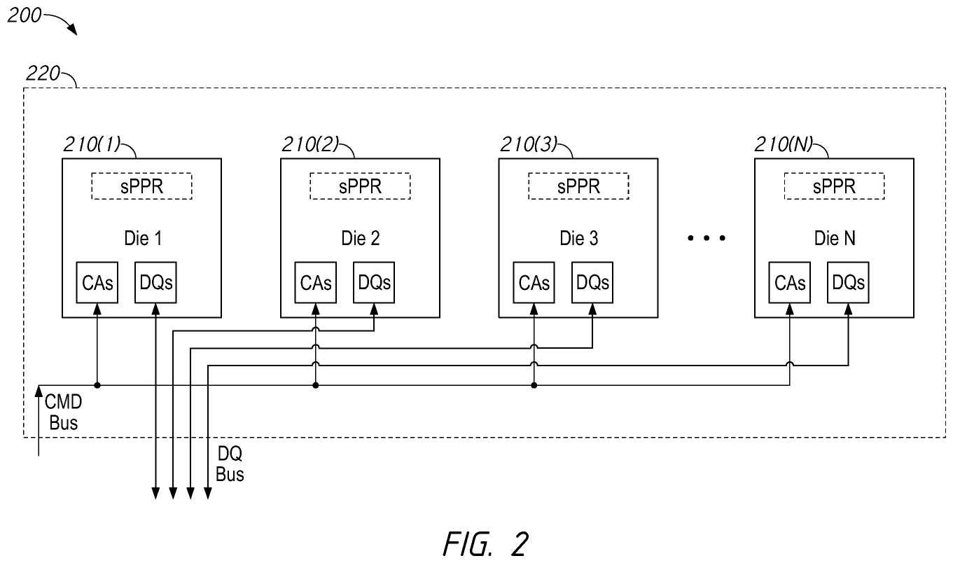

FIG. 2 illustrates a block diagram of an example memory rank according to an embodiment of the disclosure. The system 200 includes a memory rank 220 which may be an implementation of memory ranks 106(0)-106(p) of FIG. 1. In the illustrated embodiment, the memory rank 220 includes memory devices 210(1)-210(N) (e.g., “Die 1” through “Die N”), where N is a number equal to or greater than one (1). The memory devices 210(1)-210(N) may include a DRAM, a DDR memory, an LPDDR memory, a GDDR memory, or other type of memory.

The memory devices 210(1)-210(N) are each coupled to the command/address, data, and clock buses. Commands and addresses (CA) and data (DQ) may be provided between a memory system, such as 104 of FIG. 1, and a controller, such as 102 of FIG. 1, then communicated to the memory devices 210(1)-210(N) on a command bus CMD and data buses DQ internal to the memory rank 220. Each of the buses may include one or more signal lines on which signals are provided. The command bus CMD is shared by the memory devices 210(1)-210(N), and each of the memory devices 210(1)-210(N) is coupled to respective signal lines of the data bus.

In some embodiments, the memory devices 210(1)-210(N) included in a rank are provided a same control signal. The controller (e.g., 102 of FIG. 1) may provide an active control signal to select the corresponding memory rank 220 (e.g., 106(0)-106(p) of FIG. 1). While the respective control signal is active, the corresponding memory rank 220 (e.g., 106(0)-106(p) of FIG. 1) is selected to receive the commands and addresses provided on the command/address bus CMD (e.g., 108 of FIG. 1).

In operation, when an activate and a read command and associated address are provided by the controller (e.g., 102 of FIG. 1) to the memory system (e.g., 104 of FIG. 1), the memory rank 220 (e.g., 106(0)-106(p) of FIG. 1) selected by the external control signals receives the activate and read commands and associated address and communicates the command to the memory device 210(1)-210(N). The memory device 210(1)-210(N) performs a read operation to provide the controller (e.g., 102 of FIG. 1) with read data from a memory location corresponding to the associated address.

Mode registers included in each of the memory devices 210(1)-210(N) may be programmed with information for setting various operating modes and/or to select features for operation of the memory devices 210(1)-210(N). One of the settings may be for enabling a repair mode, for example, an sPPR mode, and/or enabling a repair undo mode, for example, an sPPR undo mode. When in the repair mode, repair operations may be performed. Similarly, when in the repair undo mode, repair undo operations may be performed. A controller may program information in the mode registers by using an MRW command to cause the memory devices 210(1)-210(N) to perform a MRW operation.

The memory devices 210(1)-210(N) may have sPPR resources. In other words, the memory devices 210(1)-210(N) may have repair rows (e.g., redundant rows) set aside in their memory arrays for making repairs such as during the repair mode. If a repair row is not assigned an address of an original row, that repair row is available, and the memory device 210(1)-210(N) has sPPR resources available. A repair row may include a repair flag, such as one or more bits, that can be set to indicate whether the repair row is currently assigned to an address of an original row. For example, if the repair flag is in a first state, such as an on-state, the repair row is assigned an address of an original row and thus unavailable for use. On the other hand, if the repair flag is in a second state, such as an off-state, the repair row is not assigned an address of an original row and thus is available for use, for example, to have an address of an original row assigned to it during the repair mode. The on and/or off-state of the repair flag may be indicated by a particular bit value, such as a high or low bit value, by a combination of bit values, or the like. In some embodiments, the sPPR resources may include a repair timer (e.g., 120 of FIG. 1).

FIG. 3 is a block diagram of a memory device according to at least some embodiment of the disclosure. The memory device 300 may be a semiconductor memory device, such as a DRAM device integrated on a single semiconductor chip or a memory die. In some embodiments, the memory devices 210(1)-210(N) of FIG. 2 each include the memory device 300.

The memory device 300 includes a memory array 318. The memory array 318 is shown as including a plurality of memory banks. In the embodiment of FIG. 3, the memory array 318 is shown as including a number of memory banks BANK 0-BANK N. More or fewer banks may be included in the memory array 318 of other embodiments. Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 308 and the selection of the bit lines BL is performed by a column decoder 310. In the embodiment of FIG. 3, the row decoder 308 includes a respective row decoder for each memory bank and the column decoder 310 includes a respective column decoder for each memory bank. The bit lines BL are coupled to a respective sense amplifier. Read data from the bit line BL is amplified by the sense amplifier and transferred to read/write amplifiers 320 over complementary local data lines, transfer gate, and complementary main data lines. Conversely, write data output from the read/write amplifiers 320 is transferred to the sense amplifier over the complementary main data lines, the transfer gate, and the complementary local data lines, and written in the memory cell MC coupled to the bit line BL. A number of the memory cells may be set aside as counter memory cells 340 for each row. The counter memory cells 340 may be used to store an activation count associated with the row.

Counting activations of each row may be referred to as a PRAC scheme. In some embodiments, to implement such a scheme, each word line of a memory array has an associated activation count value stored in respective counter memory cells. The activation count value is used to determine how many times that word line has been activated. When the word line is activated the activation count value may be changed by a refresh control circuit 316, for instance incremented, by a counter circuit (not shown in FIG. 3) and compared to a mitigation threshold by a comparator. If the activation count value crosses the mitigation threshold, then the address may be added to an aggressor queue and during targeted refresh operations, the addresses in the queue are used to generate refresh addresses by the refresh control circuit 316.

The counter memory cells may be initialized with an initialization value. The initialization value may be such that it is known by the memory device or falls within a known range. There may be other situations which require initialization of the activation counters, for example, if refresh requirements are violated and the counters are placed in an unknown state. Other example situations which may require activation counter initialization may be when a repair row is designated for an original row or when a repair is undone on the original row. To prevent the random state of the activation count values from causing undesired memory operations, the memory may initialize the activation count values before memory operations begin or when the counters are in an unknown state.

The activation count of the repair row may be modified with an operation such as an activation count update (ACU) operation or an activation count initialization (ACI) operation during which the activation count is initialized with an initialization value. The initialization value may be written to counter memory cells 340 of the repair row and may be a random number, pseudo-random number, semi-random number, deterministic number, or combinations thereof. The memory rank may then precharge or deactivate the repair row and exit the repair mode.

The memory device 300 also includes a repair circuit, for example, an sPPR circuit 326, which may include volatile memory elements that may store information about addresses in the memory array 318 and may be used to make non-permanent repairs. In some embodiments, there may be one repair circuit 326 for all memory banks BANK 0-BANK N. In some embodiments, each bank BANK 0-BANK N may have a separate repair circuit 326. The address information in the sPPR circuit 326 may be communicated to row latches 319. Each row latch 319 may be associated with a particular word line of the memory array 318. In some embodiments, only repair rows WLR, of the memory array 318 may be associated with the row latches 319. Row latches 319 associated with repair row addresses may be referred to as repair address latches. The repair rows WLR may, in some embodiments, be the rows designated for use in repair operations, such as when an original word line is found to be damaged. The repair rows WLR may also be referred to as repair resources or may also be referred to as sPPR resources. During a repair operation, the original row address may be latched by a particular row latch 319. In this manner, the original row address may be associated with a repair row of the memory array 318. As a result, the repair row associated with the particular row latch 319 is accessed when the original row address is to be activated, for example, for an activate command. During a repair undo operation, the original row is reassociated with the original row address and as a result, the original row is accessed when the original row address is activated. In some embodiments, information stored on the repair row may be rewritten back to the original row. The repair undo operation may be performed based on a repair undo command. In some embodiments, the repair undo command may be an external command. For example, the repair undo command may be issued by a controller (e.g., 102 of FIG. 1).

In some embodiments, when an original row is repaired, the repair circuit may enable a repair enable switch to indicate the repair. When the repair is undone with a repair undo operation, the repair enable switch associated with the original row may be cleared. For example, when the information on the repair row is reassociated with the original row, the repair enable switch may be cleared. In some embodiments, the repair circuit may block a repair undo operation by preventing the repair enable switch from being cleared.

The repair circuit 326 may include a repair timer 344. The repair timer 344 may be referred to as an sPPR timer or simply a timer. The timer 344 may count time based on the repair operation. The time 344 may be an existing circuit in the memory. The timer 344 may count time for various memory operations. The timer 344 may be a circuit that counts a number of clock cycles. For example, the timer 344 may start when the repair operation is performed. In some embodiments, the timer 344 may be a count-up timer that increases the count as time elapses. In some embodiments, the timer 344 is a countdown timer that decreases the count as time elapses. In some embodiments, when a repair undo operation is initiated, if the time on the timer 344 has reached or passed a threshold time, the repair undo operation may be blocked. For example, the repair logic 326 may block the repair undo operation by preventing the information stored on the repair row from being rewritten on the original row. In some embodiments, the repair undo operation may be blocked for all memory banks. In some embodiments, the repair undo operation may be blocked for a specific row within a specific memory bank and rank. In some embodiments, when the repair undo operation is initiated, based on the time on the timer 344, the counter memory cells associated with the original row may be modified. For example, if the time on the timer 344 has reached or passed a threshold time, the counter memory cells associated with the original row may be reset. In some embodiments, the threshold time may be a number of clock cycles. The counter memory cells of the original row may be reset to a value just below the value that would trigger a refresh. This value may be chosen because the state of the counter memory cells of the original row may be unknown or untrustworthy. In some embodiments, the reset value may be another value such as a random number, pseudo-random number, semi-random number, deterministic number, or combinations thereof. If the time on the timer 344 has not reached the threshold time, the count value on the counter memory cells associated with the original row may be incremented.

In some embodiments, the threshold amount of time may be based on the amount of time needed for the sPPR logic circuit 326 to perform a repair operation and a repair undo operation. For example, the repair and repair undo operations may include reading data from the original row and writing the data back to the repair row. The threshold amount of time may be set to be at least as much time as is required to perform these steps in some embodiments.

A row address associated with an original row of memory may be latched into a row latch 319 during a repair operation (e.g., sPPR operation). For example, a row address associated with an original row of memory may be provided to the sPPR circuit 326. In some embodiments, the original row may be a defective or damaged row. In some embodiments, the sPPR circuit 326 may perform sPPR operations while the memory die 300 is in a repair mode. For example, the memory device 300 may enter a repair mode responsive to a setting in a mode register 325 and the mode register 325 may be set responsive to an external command, such as an MRW command from a controller (e.g., 102 of FIG. 1). After the sPPR operation is complete, the memory device 300 may exit the repair mode. Exiting the repair mode may occur responsive to a second setting in the mode register 325, or in some embodiments, the memory device 300 may exit the repair mode after a pre-determined amount of time passes.

The memory device 300 may employ a plurality of external terminals that include command and address (CA) terminals coupled to a command and address bus to receive commands and addresses, clock terminals to receive clocks CK_t and CK_c, data terminals DQ to provide data, and power supply terminals to receive power supply potentials VDD, VSS, VDDQ, and VSSQ.

The clock terminals are supplied with external clocks CK_t and CK_c that are provided to an input circuit 312. The external clocks may be complementary. The input circuit 312 generates an internal clock ICLK based on the CK_t and CK_c clocks. The ICLK clock is provided to the command decoder 306 and to an internal clock generator 314. The internal clock generator 314 provides various internal clocks LCLK based on the ICLK clock. The LCLK clocks may be used for timing operation of various internal circuits. The internal data clocks LCLK are provided to the input/output circuit 322 to time operation of circuits included in the input/output circuit 322, for example, to data receivers to time the receipt of write data.

The CA terminals may be supplied with memory addresses. The memory addresses supplied to the CA terminals are transferred, via a command/address input circuit 302, to an address decoder 304. The CS_n terminals may be supplied with chip select signals, for example, CS_n(0), CS_n(1), CS_n(p)). The address decoder 304 receives the address and supplies a decoded row address XADD to the row decoder 308 and supplies a decoded column address YADD to the column decoder 310. The address decoder 304 may also supply a decoded bank address BADD, which may indicate the bank of the memory array 318 containing the decoded row address XADD and column address YADD. The CA terminals may be supplied with commands. Examples of commands include timing commands for controlling the timing of various operations, MRW commands and MRR commands for accessing mode registers, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed. The mode register commands can be used to provide repair commands.

The commands may be provided as internal command signals to a command decoder 306 via the command/address input circuit 302. The command decoder 306 includes circuits to decode the internal command signals to generate various internal signals and commands for performing operations. For example, the command decoder 306 may provide a row command signal to select a word line and a column command signal to select a bit line.

The memory device 300 may receive an access command which is a row activate command ACT. When the row activate command ACT is received, a bank address BADD and a row address XADD are timely supplied with the row activate command ACT.

The memory device 300 may receive an access command which is a read command. When a read command is received, a bank address BADD and a column address YADD are timely supplied with the read command, read data is read from memory cells in the memory array 318 corresponding to the row address XADD and column address YADD. For example, the row decoder may access the word line associated with the row latch 319 which has an address which matches XADD. The read command is received by the command decoder 306, which provides internal commands so that read data from the memory array 318 is provided to the read/write amplifiers 320. The row decoder 308 may match the address XADD to an address stored in a row latch 319, and then may access the physical row associated with that row latch 319. The read data is output to outside from the data terminals DQ via the input/output circuit 322.

The memory device 300 may receive an access command which is a write command. When the write command is received, a bank address BADD and a column address YADD are timely supplied with the write command, write data supplied to the data terminals DQ is written to memory cells in the memory array 318 corresponding to the row address and column address. The write command is received by the command decoder 306, which provides internal commands so that the write data is received by data receivers in the input/output circuit 322. The row decoder 308 may match the address XADD to an address stored in a row latch 319, and then access the physical row associated with that row latch 319. Write clocks may also be provided to the external clock terminals for timing the receipt of the write data by the data receivers of the input/output circuit 322. The write data is supplied via the input/output circuit 322 to the read/write amplifiers 320, and by the read/write amplifiers 320 to the memory array 318 to be written into the memory cell MC.

The memory device 300 may also receive commands causing it to carry out a refresh operation. The refresh signal REF may be a pulse signal which is activated when the command decoder 306 receives a signal which indicates a refresh command. In some embodiments, the refresh command may be externally issued to the memory device 300. In some embodiments, the refresh command may be periodically generated by a component of the device. In some embodiments, when an external signal indicates a self-refresh entry command, the refresh signal REF may also be activated. The refresh signal REF may be activated once immediately after command input, and thereafter may be cyclically activated at desired internal timing. Thus, refresh operations may continue automatically. A self-refresh exit command may cause the automatic activation of the refresh signal REF to stop and return to an IDLE state.

The refresh signal REF is supplied to the refresh control circuit 316. The refresh control circuit 316 supplies a refresh row address RXADD to the row decoder 308, which may refresh a word line WL indicated by the refresh row address RXADD. The refresh control circuit 316 may control a timing of the refresh operation and may generate and provide the refresh address RXADD. The refresh control circuit 316 may be controlled to change details of the refreshing address RXADD, such as how the refresh address is calculated, the timing of the refresh addresses, or may operate based on internal logic. In some embodiments, the refresh control circuit 316 may perform both refresh operations, where the word lines of the memory array 318 are refreshed in a sequence, and targeted refresh operations, where specific word lines of the memory are targeted for a refresh out of sequence from the refresh operations. Targeted refresh operations may be performed when an aggressor row is identified based on an associated activation count for the row. As previously described, activation counts may be stored by counter memory cells 340.

The power supply terminals are supplied with power supply potentials VDD and VSS. The power supply potentials VDD and VSS are supplied to an internal voltage generator circuit 324. The internal voltage generator circuit 324 generates various internal potentials VPP, VOD, VARY, VPERI, and the like based on the power supply potentials VDD and VSS supplied to the power supply terminals. The internal potential VPP is mainly used in the row decoder 308, the internal potentials VOD and VARY are mainly used in the sense amplifiers SAMP included in the memory array 318, and the internal potential VPERI is used in many peripheral circuit blocks.

The power supply terminals are also supplied with power supply potentials VDDQ and VSSQ. The power supply potentials VDDQ and VSSQ are supplied to the input/output circuit 322. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 322 so that power supply noise generated by the input/output circuit 322 does not propagate to the other circuit blocks.

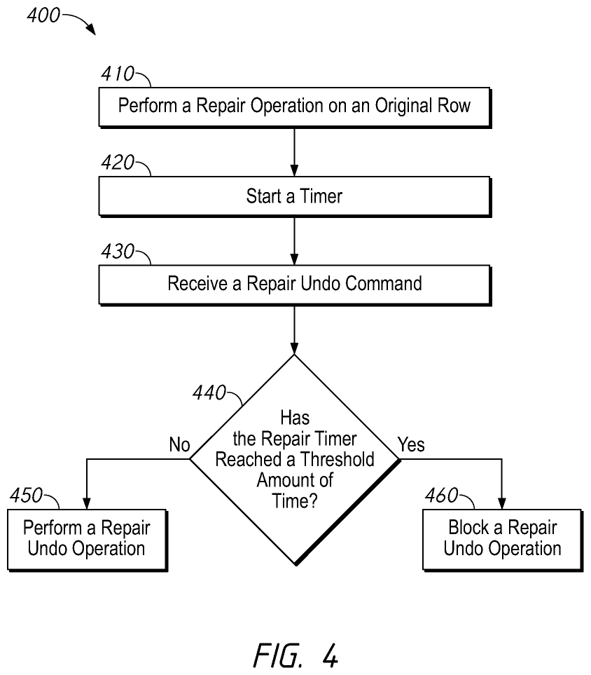

FIG. 4 is a flow chart of a repair operation according to some embodiments of the present disclosure. The method 400 may, in some embodiments, be implemented by one or more of the components described in FIGS. 1-3. The method 400 includes blocking a repair undo operation following a repair operation on a memory device when a timer has reached a threshold amount of time.

The method 400 may begin at block 410, which describes a memory device performing a repair operation on an original row of the memory. In some embodiments, the repair operation may be an sPPR operation. The memory device (e.g., 210(1)-210(N) of FIGS. 2 and/or 300 of FIG. 3) may perform the repair operation responsive to a repair command. In some embodiments, the repair command may be issued by a memory controller (e.g., 102 of FIG. 1). For example, the repair command may be an MRW command that sets a register of a mode register (e.g., 325 of FIG. 3) and enables the repair mode. The method 400 may proceed to block 420.

Block 420 describes starting a timer. The timer may be an implementation of timer 120 of FIG. 1 and/or timer 344 of FIG. 3. In some embodiments, the timer may be activated by a repair circuit (e.g., sPPR circuit 326 of FIG. 3) responsive to performing the repair operation. In some embodiments, the timer (e.g., 120 of FIG. 1) may be located in the controller (e.g., 102 of FIG. 1). In some embodiments, the time (e.g., 344 of FIG. 3) may be part of the repair logic (e.g., 326 of FIG. 3) of a memory device. The method 400 may proceed to block 430.

Block 430 describes receiving a repair undo command. In some embodiments, the repair undo command may be issued by a memory controller (e.g., 102 of FIG. 1). For example, the repair undo command may be an MRW command that sets a register of a mode register (e.g., 325 of FIG. 3) and enables the repair undo mode. The method 400 may proceed to block 440.

Block 440 describes determining if the timer has reached a threshold amount of time. In some embodiments, the timer (e.g., 120 of FIGS. 1 and/or 344 of FIG. 3) may start responsive to the repair operation being performed. In some embodiments, the threshold amount of time may be based on the amount of time for a refresh period or the maximum amount of time a row can go between refresh operations. In some embodiments, the threshold amount of time may be based on the amount of time needed to perform a repair operation and a repair undo operation. The threshold amount of time may be a setting, such as a mode register setting or a setting in the sPPR circuit (e.g., 326 of FIG. 3). The threshold amount of time may be a number of clock cycles. When the memory device receives the repair undo command and the timer has not reached the threshold amount of time, the method 400 may proceed to block 450.

Block 450 describes performing a repair undo operation. The repair undo operation may be performed responsive to the repair undo command. During the repair undo operation, the repair logic (e.g., 326 of FIG. 3) may write the data stored on the repair row back to the original row and the original row address may no longer be associated with the repair row. In some embodiments, the activation count value associated with the original row is changed (e.g., incremented in some embodiments) for the repair undo operation.

When the memory device receives the repair undo command and the timer has reached the threshold amount of time, the method 400 may proceed to block 460. Block 460 describes blocking a repair undo operation. In some embodiments, the repair undo operation may be blocked for all memory banks. In some embodiments, the repair undo operation may be blocked for a specific row within a specific memory bank and rank. In some embodiments, the repair logic (e.g., 326 of FIG. 3) may block the repair undo operation by not allowing a repair enable switch to be cleared. For example, the repair enable switch may be set by a repair operation to indicate that an original row has been repaired and a repair undo operation may disable the repair enable switch to indicate that the original row is no longer repaired. In some embodiments, a memory controller (e.g., 102 of FIG. 1) may set a repair undo disable flag that causes the repair logic (e.g., 326 of FIG. 3) to block repair undo operations, or in other words prevent repair undo operations from occurring. In some embodiments, the repair undo operation may be blocked until the next power cycle. In some embodiments, the memory controller (e.g., 102 of FIG. 1) may block the repair undo operation by setting a repair undo disable flag in the memory controller. For example, the repair undo disable flag may prevent the controller from transmitting repair undo commands to the memory device. In some embodiments, the memory controller may block the transmission of repair undo commands to all banks of a memory device or to a particular memory bank.

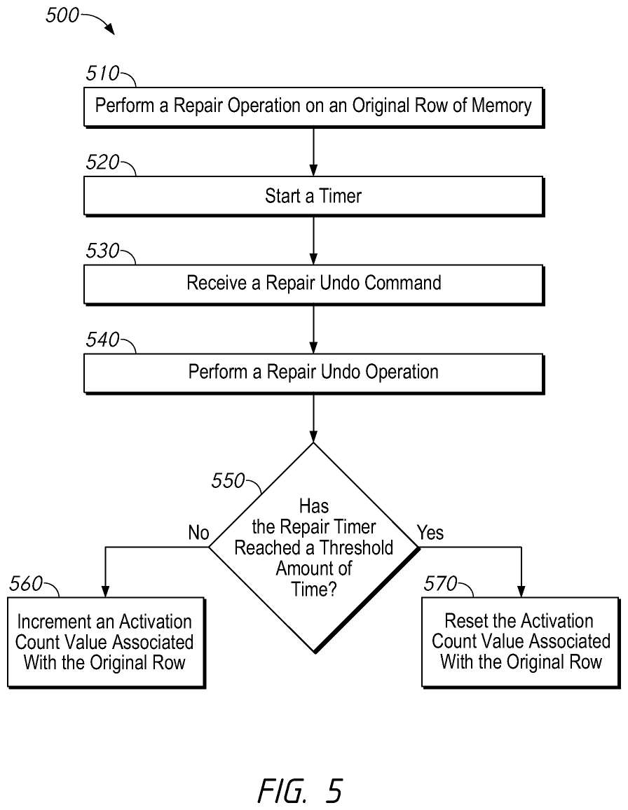

FIG. 5 is a flow chart of a repair undo operation according to some embodiments of the present disclosure. The method 500 may, in some embodiments, be implemented by one or more of the components described in FIGS. 1-3. The method 500 includes resetting an activation count value associated with an original row of memory on a memory device when a timer has reached a threshold amount of time.

The method 500 may begin at block 510, which describes a memory device performing a repair operation on an original row of the memory. In some embodiments, the repair operation may be an sPPR operation. The memory device (e.g., 210(1)-210(N) of FIGS. 2 and/or 300 of FIG. 3) may perform the repair operation responsive to a repair command. In some embodiments, the repair command may be issued by a memory controller (e.g., 102 of FIG. 1). For example, the repair command may be an MRW command that sets a register of a mode register (e.g., 325 of FIG. 3) and enables the repair mode. The method 500 may proceed to block 520.

Block 520 describes starting a timer. The timer may be an implementation of timer 120 of FIG. 1 and/or timer 344 of FIG. 3. In some embodiments, the repair time may be activated by a repair circuit (e.g., sPPR circuit 326 of FIG. 3) responsive to performing the repair operation. In some embodiments, the repair timer (e.g., 120 of FIG. 1) may be located in the controller (e.g., 102 of FIG. 1). The method 500 may proceed to block 530.

Block 530 describes receiving a repair undo command. In some embodiments, the repair undo command may be issued by a memory controller (e.g., 102 of FIG. 1). For example, the repair undo command may be an MRW command that sets a register of a mode register (e.g., 325 of FIG. 3) and enables the repair undo mode. The method 500 may proceed to block 540.

Block 540 describes performing a repair undo operation. The repair undo operation may be performed responsive to the repair undo command. During the repair undo operation, the repair logic (e.g., 326 of FIG. 3) may write the data stored on the repair row back to the original row and the original row address may no longer be associated with the repair row. In some embodiments, the repair undo operation may disable a repair enable switch. The method 500 may proceed to block 550.

Block 550 describes determining if the timer has reached a threshold amount of time. In some embodiments, the timer (e.g., 120 of FIGS. 1 and/or 344 of FIG. 3) may start responsive to the repair operation being performed. In some embodiments, the threshold amount of time may be based on the amount of time for a refresh period or the maximum amount of time a row can go between refresh operations. In some embodiments, the threshold amount of time may be based on the amount of time needed to perform a repair operation and a repair undo operation. The threshold amount of time may be a setting, such as a mode register setting or a setting in the sPPR circuit (e.g., 326 of FIG. 3). In some embodiments, the threshold amount of time may be a number of clock cycles. When the memory device receives the repair undo command and the timer has not reached the threshold amount of time, the method 500 may proceed to block 560.

Block 560 describes incrementing an activation count value associated with the original row. In some embodiments, the activation count value associated with the original row may reflect an accurate activation count when the timer has not reached the threshold amount of time. Thus, when the repair undo operation is performed, the activation count value is incremented to reflect the activation that occurs as part of the repair undo operation. When the repair timer reaches the threshold amount of time, the method 500 may proceed to block 570.

Block 570 describes resetting an activation count value associated with the original row. When the timer (e.g., 120 of FIGS. 1 and/or 344 of FIG. 3) reaches the threshold amount of time, responsive to a repair undo operation on the repair row, the activation count value associated with the original may be reset. For example, the counter memory cells of the original row may be reset. For example, the counter memory cells of the original row may be reset with an ACU operation. In some embodiments, the counter memory cells of the original row may be reset to a value near and below a trigger value for a targeted refresh operation. This value may be chosen because the state of the counter memory cells of the original row may be unknown or untrustworthy. In some embodiments, the reset value may be another value such as a random number, pseudo-random number, semi-random number, deterministic number, or combinations thereof.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of memory banks each including a memory array comprising a plurality of rows including an original row and a repair row;
a repair circuit configured to:
perform a repair operation on the original row based on a repair command;
start a timer responsive to performing the repair operation;
perform a repair undo operation on the repair row based on a repair undo command when the timer has not reached a threshold amount of time; and
block the repair undo operation when the timer reaches a threshold amount of time.

2. The apparatus of claim 1, wherein the threshold amount of time is based on an amount of time to perform the repair operation and the repair undo operation.

3. The apparatus of claim 1, wherein the repair undo operation is blocked by setting a repair undo disable flag in the repair circuit.

4. The apparatus of claim 3, wherein the repair undo disable flag is reset by a power cycle.

5. The apparatus of claim 1, wherein the repair circuit is further configured to block the repair undo operation on all memory banks of the plurality of memory banks.

6. The apparatus of claim 1, wherein the repair command and the repair undo command are issued by a memory controller.

7. A system comprising:
a memory controller configured to:
transmit a repair command and a repair undo command;
start a timer responsive to transmitting the repair command; and
block transmission of the repair undo command when the timer reaches a threshold amount of time; and
a memory device coupled to the memory controller and configured to receive the repair command, wherein the memory device includes:
a memory rank comprising a plurality of memory dies coupled to the memory controller and each memory die of the plurality of memory dies comprising:
a memory array comprising a plurality of rows;
a repair circuit configured to:
perform a repair operation on the memory array based on the repair command; and
perform a repair undo operation based on the repair undo command when the timer has not reached the threshold amount of time.

8. The system of claim 7, wherein the threshold amount of time is based on an amount of time to perform the repair operation and the repair undo operation.

9. The system of claim 7, wherein the repair undo operation is blocked by setting a repair undo disable flag that causes the memory controller to stop transmitting repair undo commands.

10. The system of claim 9, wherein the repair undo disable flag is reset by a power cycle.

11. The system of claim 7, wherein the memory controller is further configured to block the repair undo command for all memory banks of the plurality of memory banks.

12. The system of claim 7, wherein the memory array includes a plurality of memory banks that include the plurality of rows and wherein the memory rank is included in a plurality of memory ranks, the memory controller is further configured to block the repair undo command for a specific row of the plurality of rows within a specific memory bank and rank of a plurality of memory banks and ranks.

13. A method comprising:
at a memory, receiving a repair command;
entering a repair mode;
performing a repair operation on an original row of the memory responsive to the repair command;
starting a timer responsive to performing the repair operation;
receiving a repair undo command;
performing a repair undo operation on a repair row of the memory associated with the original row based on the repair undo command when the timer has not reached a threshold amount of time;
blocking the repair undo operation if the timer reaches the threshold amount of time; and
exiting the repair mode.

14. The method of claim 13, wherein the threshold amount of time is based on an amount of time to perform the repair operation and the repair undo operation.

15. The method of claim 13, wherein the repair undo operation is blocked by setting a repair undo disable flag.

16. The method of claim 15, wherein the repair undo disable flag is reset by a power cycle.

17. The method of claim 13, wherein the memory comprises a plurality of memory banks and blocking the repair undo operation causes the repair undo operation to be blocked on all memory banks of the plurality of memory banks.

18. The method of claim 13, wherein the repair command and the repair undo command are issued by a memory controller.
